(19) United States
(12) Patent Application Publication
(10) Pub. No.: US 2025/0174582 A1
(43) Pub. Date: May 29, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Wen-Yang LI, Taichung City (TW); Chih-Hsien CHIU, Taichung City (TW); Chin-Wen LAI, Taichung City (TW); Ko-Wei CHANG, Taichung City (TW); Chien-Min CHENG, Taichung City (TW); Shih-Shiung KUO, Taichung City (TW); Wen-Jung TSAI, Taichung City (TW)

(21) Appl. No.: 18/673,978

(22) Filed: May 24, 2024

(30) Foreign Application Priority Data
Nov. 27, 2023 (TW) 112145870

(51) Int. Cl. H01L 23/66; H01L 21/48; H01L 21/56; H01L 23/31; H01L 23/498; H01L 23/552; H01L 25/16

(52) U.S. Cl. CPC H01L 23/66; H01L 21/4853; H01L 21/56; H01L 23/3135; H01L 23/49811; H01L 23/552; H01L 25/16; H01L 2223/6677

(57) ABSTRACT

An electronic package is provided, in which a package module is disposed on a first surface of a carrier structure, and the package module is covered by a shielding layer, so that the shielding layer is formed on one part of a side surface of the carrier structure without being formed on the other part of the side surface, and thus a second surface of the carrier structure can be used as an antenna transmitting surface and/or an antenna receiving surface to prevent the shielding layer from interfering with the reception and the transmission of the carrier structure.

### CROSS-REFERENCE TO RELATED APPLICATIONS

The present application is based upon and claims the right of priority to TW Patent Application No. 112145870, filed Nov. 27, 2023, the disclosure of which is hereby incorporated by reference herein in its entirety for all purposes.

### BACKGROUND

### 1. Technical Field

The present disclosure relates to a semiconductor device, and more particularly, to an electronic package suitable for communication products and a manufacturing method thereof.

### 2. Description of Related Art

Nowadays, wireless communication technology has been widely applied for various consumer electronic products (such as mobile phones, tablet computers, etc.) to facilitate the reception or transmission of various wireless signals. At the same time, in order to meet the portability and internet access convenience of consumer electronic products, the manufacturing and design of wireless communication modules are developed toward the requirements of being light, thin, short and small, wherein the patch antenna is widely used in wireless communication modules of electronic products due to its characteristics of small volume, light weight and easy manufacturing.

FIG. 1 is a schematic cross-sectional view of a conventional wireless communication module 1. As shown in FIG. 1, the wireless communication module 1 comprises: a package substrate 10, a plurality of electronic components 11 disposed on the package substrate 10, an antenna structure 15, a shielding layer 14, and an encapsulation colloid 12. The electronic components 11 are disposed on the package substrate 10 and electrically connected to the package substrate 10. The antenna structure 15 is electrically connected to the electronic components 11. The encapsulation colloid 12 covers the electronic components 11. The shielding layer 14 covers the package substrate 10 and the encapsulation colloid 12 to prevent electromagnetic interference (EMI).

However, in the conventional wireless communication module 1, the metal shielding layer 14 covers side surfaces 10c of the package substrate 10 and shields the antenna structure 15. As a result, the antenna functions of the antenna structure 15 cannot function effectively.

Therefore, how to overcome the aforementioned drawbacks of the prior art has become an urgent issue for industries to be addressed at present.

### SUMMARY

In view of the aforementioned shortcomings of the prior art, the present disclosure provides an electronic package, which comprises: a carrier structure having a first surface, a second surface opposing the first surface, and a side surface adjacent to the first surface and the second surface, wherein the side surface is formed with a recess; a package module disposed on the first surface of the carrier structure; and a shielding layer formed on the first surface of the carrier structure and covering the package module, wherein the shielding layer is further formed on a part of the side surface of the carrier structure rather than on the recess.

The present disclosure further provides a method of manufacturing an electronic package, the method comprises: providing at least one package module on a carrier structure, wherein the carrier structure has a first surface, a second surface opposing the first surface, and a side surface adjacent to the first surface and the second surface, wherein the package module is disposed on the first surface of the carrier structure; forming a shielding layer on the first surface and the side surface of the carrier structure to cover the package module; and forming a recess on the side surface of the carrier structure to remove a portion of the shielding layer on the side surface of the carrier structure corresponding to the recess, so that the shielding layer is formed on a part of the side surface rather than on the recess.

In the aforementioned electronic package and method, the carrier structure has an insulating material and a wiring layer formed on the insulating material, and the wiring layer is electrically connected to the package module.

In the aforementioned electronic package and method, the present disclosure further comprises disposing at least one electronic connector on the carrier structure. Moreover, the present disclosure further comprises covering the electronic connector by a protective cover, and forming the shielding layer on the protective cover, then removing the protective cover to remove the shielding layer on the protective cover, so that the shielding layer is not formed on the electronic connector.

In the aforementioned electronic package and method, the recess is adjacent to the second surface and the side surface, and an edge of the carrier structure has a notched appearance.

In the aforementioned electronic package and method, the carrier structure is an antenna substrate. For instance, the carrier structure has an antenna portion, and the shielding layer is not formed on the side surface corresponding to the antenna portion.

In the aforementioned electronic package and method, the shielding layer is not formed on the second surface of the carrier structure.

In the aforementioned electronic package and method, the package module comprises at least one electronic component electrically connected to the carrier structure, and an encapsulation layer covering the electronic component, wherein the shielding layer is formed on the encapsulation layer. For instance, the package module further comprises a circuit structure carrying the electronic component, wherein the circuit structure is disposed on the first surface of the carrier structure via a plurality of conductive components.

It can be seen from the above that, in the electronic package and the manufacturing method thereof of the present disclosure, the shielding layer is formed on one part of the side surface of the carrier structure without being formed on the other part (i.e., the recess) of the side surface, so that the second surface of the carrier structure can be used as the antenna transmitting surface and/or the antenna receiving surface so as to prevent the shielding layer from interfering with the reception and the transmission of the carrier structure (or the antenna portion). Hence, compared to the prior art, the electronic package of the present disclosure can effectively operate the antenna functions, thereby improving the antenna gain.

### BRIEF DESCRIPTION OF THE DRAWINGS

FIG. 1 is a schematic cross-sectional view of a conventional wireless communication module.

FIG. 2A, FIG. 2B, FIG. 2C-1 and FIG. 2D are schematic cross-sectional views illustrating a manufacturing method of an electronic package of the present disclosure.

FIG. 2C-2 is a schematic cross-sectional view illustrating another method of FIG. 2C-1.

FIG. 3 is a schematic cross-sectional view of another embodiment of FIG. 2D.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

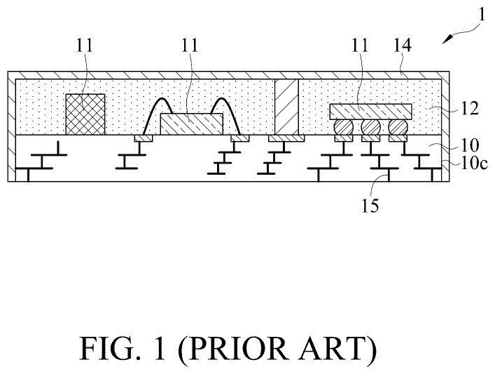

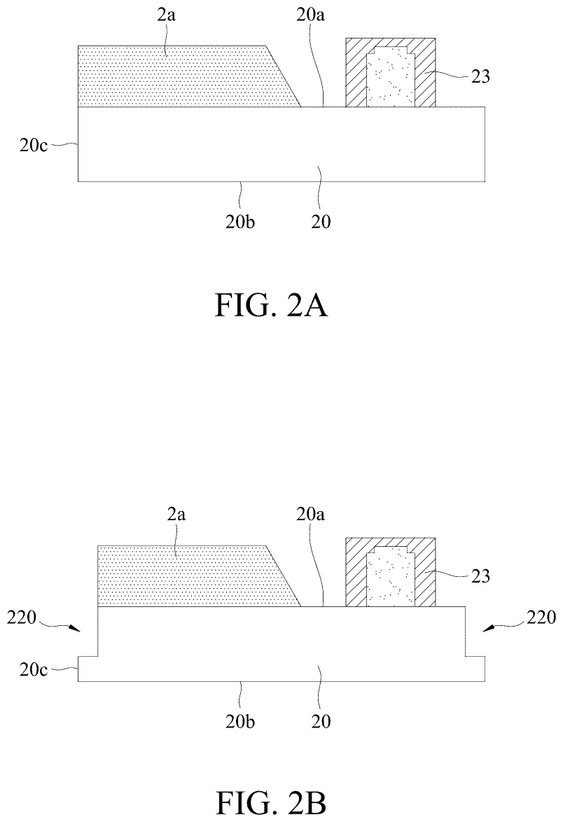

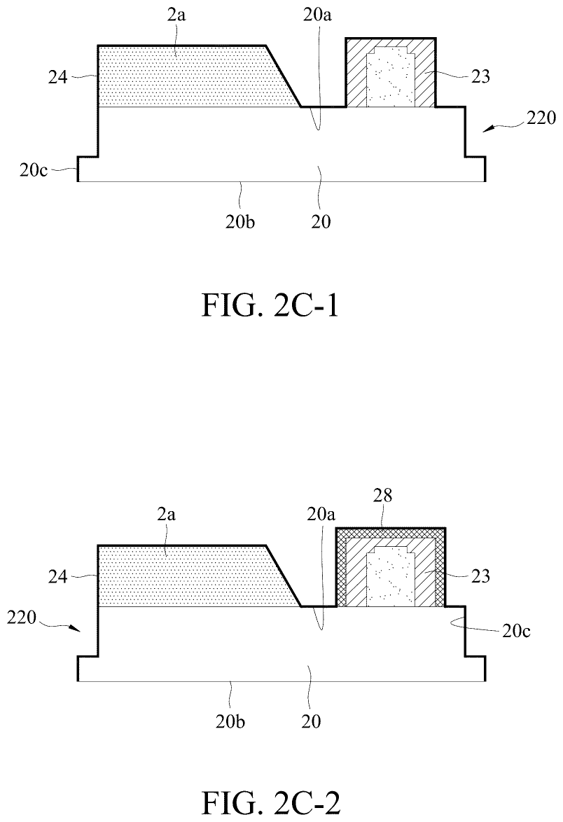

FIG. 2A, FIG. 2B, FIG. 2C-1 and FIG. 2D are schematic cross-sectional views illustrating a manufacturing method of an electronic package 2 of the present disclosure.

As shown in FIG. 2A, a package module 2a is disposed on a carrier structure 20, and at least one electronic connector 23 is disposed on the carrier structure 20.

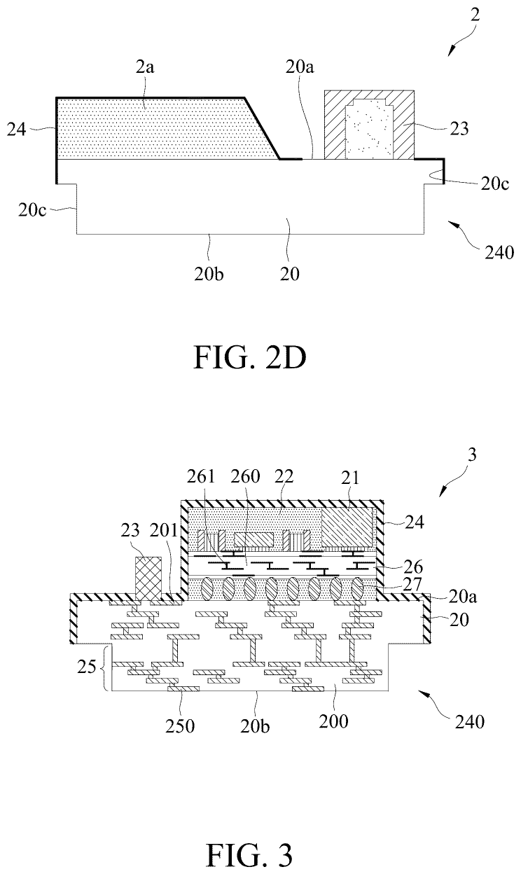

In an embodiment, as shown in FIG. 3, the package module 2a can comprise at least one electronic component 21 electrically connected to the carrier structure 20, and an encapsulation layer 22 covering the electronic component 21.

The carrier structure 20 is, for instance, a package substrate having a core layer and a circuit structure, or a coreless circuit structure. The carrier structure 20 has a first surface 20a, a second surface 20b opposing the first surface 20a, and side surfaces 20c adjacent to the first surface 20a and the second surface 20b, such that the package module 2a is disposed on the first surface 20a of the carrier structure 20.

In an embodiment, as shown in FIG. 3, the carrier structure 20 has an insulating material 200 and a wiring layer 201 formed on the insulating material 200, and is of a fan-out redistribution layer (RDL) specification. For instance, the material for forming the wiring layer 201 is copper, and the insulating material 200 is a dielectric material such as polybenzoxazole (PBO), polyimide (PI), prepreg (PP), etc., or a solder-resist material such as solder mask (e.g., green solder mask), graphite (e.g., ink), etc.

The electronic component 21 is disposed on the first surface 20a of the carrier structure 20, and the electronic component 21 is an active element, a passive element, or a combination of the active element and the passive element, wherein the active element is, for instance, a radio-frequency (RF) semiconductor chip, and the passive element is, for instance, a resistor, a capacitor, or an inductor.

In an embodiment, the electronic component 21 can be electrically connected to the wiring layer 201 of the carrier structure 20 by flip-chip method, wire-bonding method, directly contacting the wiring layer 201 of the carrier structure 20, or other suitable methods, and the present disclosure is not limited to as such.

The encapsulation layer 22 is formed on the first surface 20a of the carrier structure 20 and covers the electronic component 21.

In an embodiment, the encapsulation layer 22 is made of insulating material such as polyimide (PI), dry film, package colloid such as epoxy (epoxy resin), or molding compound, and the present disclosure is not limited to as such.

Moreover, the surface of the at least one electronic component 21 can be exposed from the surface of the encapsulation layer 22 by a leveling process, such that the surface of the encapsulation layer 22 is flush with the surface of the electronic component 21. For instance, the leveling process removes a portion of the material of the electronic component 21 and a portion of the material of the encapsulation layer 22 by grinding.

Furthermore, the package module 2a can also be arranged with a circuit structure 26 carrying the electronic component 21 according to requirements, such that the circuit structure 26 is disposed on the first surface 20a of the carrier structure 20 via a plurality of conductive components 27, and the encapsulation layer 22 also covers the plurality of conductive components 27. For instance, the circuit structure 26 has a dielectric material 260 and a circuit layer 261 formed on the dielectric material 260, and is of a fan-out redistribution layer (RDL) specification. For instance, the material for forming the circuit layer 261 is copper, and the dielectric material 260 is made of polybenzoxazole (PBO), polyimide (PI), prepreg (PP), solder-resist material (green solder mask), graphite (ink), or others.

In addition, the electronic component 21 can be electrically connected to the circuit layer 261 of the circuit structure 26 by flip-chip method, wire-bonding method, or other methods, and the circuit layer 261 of the circuit structure 26 is electrically connected to the wiring layer 201 of the carrier structure 20 via the plurality of conductive components 27.

As shown in FIG. 2B, at least one groove 220 is formed on the first surface 20a of the carrier structure 20.

In an embodiment, a half-cutting method can be adopted to cut along the side surface 20c of the carrier structure 20 to form the step-shaped groove 220 on the first surface 20a of the carrier structure 20.

As shown in FIG. 2C-1, a shielding layer 24 is formed on the groove 220, the first surface 20a of the carrier structure 20, the package module 2a, and the electronic connector 23.

In an embodiment, the shielding layer 24 is not formed on the second surface 20b of the carrier structure 20.

Moreover, the shielding layer 24 such as a metal layer can be formed by sputtering, vapor deposition, electroplating, chemical plating, or foiling, and the present disclosure is not limited to as such.

Furthermore, as shown in FIG. 2C-2, the electronic connector 23 can be covered with a protective cover 28 at first, then the shielding layer 24 is formed on the protective cover 28, thereby facilitating the removal of the shielding layer 24 disposed on the electronic connector 23 in the subsequent process.

As shown in FIG. 2D, the shielding layer 24 on the electronic connector 23 is removed, and a recess 240 is formed on the side surface 20c of the carrier structure 20 to remove a portion of the shielding layer 24 on the carrier structure 20 corresponding to the recess 240, so that the shielding layer 24 is formed on one part of the side surface 20c of the carrier structure 20, and the shielding layer 24 is not formed on the other part (i.e., the surface of the recess 240) of the side surface 20c.

In an embodiment, a half-cutting method can be adopted to cut along the intersection of the side surface 20c and the second surface 20b of the carrier structure 20 so as to form the step-shaped recess 240 at the intersection of the second surface 20b and the side surface 20c of the carrier structure 20, such that the edge of the carrier structure 20 presents a notched appearance such as an inversed L shape when viewed from the side of the edge of the carrier structure 20.

Furthermore, if the process shown in FIG. 2C-2 is continued, by removing the protective cover 28, the shielding layer 24 on the protective cover 28 is also removed to expose the electronic connector 23, so that the shielding layer 24 is not formed on the electronic connector 23.

In addition, as shown in FIG. 3, the carrier structure 20 can be an antenna substrate, and an antenna portion 25 having an antenna layer 250 is formed inside the carrier structure 20, such that the second surface 20b of the carrier structure 20 is served as a transmitting surface and/or a receiving surface of the antenna portion 25, that is, the antenna portion 25 corresponds to the space of the carrier structure 20 surrounded by the recess 240, so that the side surface 20c (i.e., the wall surface of the recess 240) corresponding to the transmitting end of the second surface 20b of the carrier structure 20 has no shielding mechanism, and a shielding mechanism (the shielding layer 24) is arranged on the side surface 20c corresponding to the signal transmission circuit (the contact of the wiring layer 201 on the first surface 20a).

Therefore, in the manufacturing method of the present disclosure, the shielding layer 24 is formed on only one part of the side surface 20c of the carrier structure 20 without being formed on the other part of the side surface 20c. Hence, compared to the prior art, the second surface 20b of the carrier structure 20 in the electronic package 2, 3 of the present disclosure can be served as the antenna transmitting surface and/or the antenna receiving surface so as to prevent the shielding layer 24 from interfering with the reception and the transmission of the carrier structure 20 (the antenna portion 25), so that the electronic package 2, 3 of the present disclosure can effectively operate the antenna functions, thereby improving the antenna gain.

The present disclosure also provides an electronic package 2, 3, which comprises: a carrier structure 20, at least one package module 2a, and a shielding layer 24.

The carrier structure 20 has a first surface 20a, a second surface 20b opposing the first surface 20a, and side surfaces 20c adjacent to the first surface 20a and the second surface 20b, wherein a recess 240 is formed on the side surface 20c.

The package module 2a is disposed on the first surface 20a of the carrier structure 20.

The shielding layer 24 is formed on the first surface 20a of the carrier structure 20 and covers the package module 2a, wherein the shielding layer 24 is further formed on one part of the side surface 20c of the carrier structure 20 rather than on the other part of the side surface 20c (i.e., the shielding layer 24 is not formed on the recess 240).

In an embodiment, the carrier structure 20 is formed with an insulating material 200 and a wiring layer 201 formed on the insulating material 200, such that the wiring layer 201 is electrically connected to the package module 2a.

In an embodiment, at least one electronic connector 23 is disposed on the carrier structure 20. For instance, the shielding layer 24 is not formed on the electronic connector 23.

In an embodiment, the recess 240 is adjacent to the second surface 20b and the side surface 20c, such that the edge of the carrier structure 20 has a notched appearance.

In an embodiment, the carrier structure 20 is an antenna substrate. For instance, the carrier structure 20 has an antenna portion 25, wherein the antenna portion 25 corresponds to the position of the recess 240, and the shielding layer 24 is not formed on the side surface 20c corresponding to the antenna portion 25.

In an embodiment, the shielding layer 24 is not formed on the second surface 20b of the carrier structure 20.

In an embodiment, the package module 2a comprises at least one electronic component 21 electrically connected to the carrier structure 20, and an encapsulation layer 22 covering the electronic component 21, such that the shielding layer 24 is formed on the encapsulation layer 22. For instance, the package module 2a further comprises a circuit structure 26 carrying the electronic component 21, such that the circuit structure 26 is disposed on the first surface 20a of the carrier structure 20 via a plurality of conductive components 27.

To sum up, in the electronic package and the manufacturing method thereof of the present disclosure, the shielding layer is formed on only one part of the side surface of the carrier structure without being formed on the other part (the part formed with a recess) of the side surface, so that the second surface of the carrier structure (corresponding to the position of the recess) in the electronic package of the present disclosure can be served as the antenna transmitting surface and/or the antenna receiving surface so as to prevent the shielding layer from interfering with the reception and the transmission of the carrier structure (or the antenna portion). Therefore, the electronic package of the present disclosure can effectively operate the antenna functions, thereby improving the antenna gain.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure having a first surface, a second surface opposing the first surface, and a side surface adjacent to the first surface and the second surface, wherein the side surface is formed with a recess;
a package module disposed on the first surface of the carrier structure; and
a shielding layer formed on the first surface of the carrier structure and covering the package module, wherein the shielding layer is further formed on a part of the side surface of the carrier structure rather than on the recess.

2. The electronic package of claim 1, wherein the carrier structure has an insulating material and a wiring layer formed on the insulating material, and the wiring layer is electrically connected to the package module.

3. The electronic package of claim 1, further comprising at least one electronic connector disposed on the carrier structure.

4. The electronic package of claim 3, wherein the shielding layer is not formed on the electronic connector.

5. The electronic package of claim 1, wherein the recess is adjacent to the second surface and the side surface, and an edge of the carrier structure has a notched appearance.

6. The electronic package of claim 1, wherein the carrier structure is an antenna substrate.

7. The electronic package of claim 6, wherein the carrier structure has an antenna portion, and the shielding layer is not formed on the side surface corresponding to the antenna portion.

8. The electronic package of claim 1, wherein the shielding layer is not formed on the second surface of the carrier structure.

9. The electronic package of claim 1, wherein the package module comprises at least one electronic component electrically connected to the carrier structure, and an encapsulation layer covering the electronic component, wherein the shielding layer is formed on the encapsulation layer.

10. The electronic package of claim 9, wherein the package module further comprises a circuit structure carrying the electronic component, wherein the circuit structure is disposed on the first surface of the carrier structure via a plurality of conductive components.

11. A method of manufacturing an electronic package, comprising:
providing at least one package module on a carrier structure, wherein the carrier structure has a first surface, a second surface opposing the first surface, and a side surface adjacent to the first surface and the second surface, wherein the package module is disposed on the first surface of the carrier structure;
forming a shielding layer on the first surface and the side surface of the carrier structure to cover the package module; and
forming a recess on the side surface of the carrier structure to remove a portion of the shielding layer on the side surface of the carrier structure corresponding to the recess, so that the shielding layer is formed on a part of the side surface rather than on the recess.

12. The method of claim 11, wherein the carrier structure has an insulating material and a wiring layer formed on the insulating material, and the wiring layer is electrically connected to the package module.

13. The method of claim 11, further comprising disposing at least one electronic connector on the carrier structure.

14. The method of claim 13, further comprising covering the electronic connector by a protective cover, and forming the shielding layer on the protective cover, then removing the protective cover to remove the shielding layer on the protective cover, so that the shielding layer is not formed on the electronic connector.

15. The method of claim 11, wherein the recess is adjacent to the second surface and the side surface, and an edge of the carrier structure has a notched appearance.

16. The method of claim 11, wherein the carrier structure is an antenna substrate.

17. The method of claim 16, wherein the carrier structure has an antenna portion, and the shielding layer is not formed on the side surface corresponding to the antenna portion.

18. The method of claim 11, wherein the shielding layer is not formed on the second surface of the carrier structure.

19. The method of claim 11, wherein the package module comprises at least one electronic component electrically connected to the carrier structure, and an encapsulation layer covering the electronic component, wherein the shielding layer is formed on the encapsulation layer.

20. The method of claim 19, wherein the package module further comprises a circuit structure carrying the electronic component, wherein the circuit structure is disposed on the first surface of the carrier structure via a plurality of conductive components.
